(19) United States
(12) Patent Application Publication
(10) Pub. No.: US 2025/0246467 A1
(43) Pub. Date: Jul. 31, 2025

(54) MANUFACTURING APPARATUS OF SEMICONDUCTOR DEVICE

(71) Applicant: SAMSUNG ELECTRONICS CO., LTD., Suwon-si (KR)

(72) Inventors: Young YOON, Suwon-si (KR); Juhyun Kim, Suwon-si (KR); Jongmin Song, Swuon-si (KR); Sangrok Oh, Suwon-si (KR); Byoung Min Kr, Suwon-si (KR); Yongwoo Lee, Suwon-si (KR); Juneeok Leem, Suwon-si (KR); Younsok Choi, Suwon-si (KR); Gyoseon Choo, Suwon-si (KR); Minyoung Hur, Suwon-si (KR)

(73) Assignee: SAMSUNG ELECTRONICS CO., LTD., Suwon-si (KR)

(21) Appl. No.: 18/762,387

(22) Filed: Jul. 2, 2024

(30) Foreign Application Priority Data
Jan. 29, 2024 (KR) 10-2024-0013459

(51) Int. Cl. H01L 21/68; H01L 21/66; H01L 21/67

(52) U.S. Cl. CPC H01L 21/681; H01L 21/67259; H01L 22/20

(57) ABSTRACT

Embodiments include a manufacturing apparatus of a semiconductor device. The manufacturing apparatus may include a wafer-type magnetic sensor and a calibrator. The wafer-type magnetic sensor may include a wafer body portion and a measuring sensor at or in the wafer body portion. The calibrator may be configured to perform an offset calibration of the measuring sensor.

### CROSS-REFERENCE TO RELATED APPLICATION

This application claims priority to and the benefit of Korean Patent Application No. 10-2024-0013459, filed in the Korean Intellectual Property Office on Jan. 29, 2024, the entire contents of which are incorporated herein by reference.

### BACKGROUND

### 1. Field

Embodiments of the present disclosure relate to a manufacturing apparatus of a semiconductor device.

### 2. Description of Related Art

A semiconductor device may have a small size while performing various functions, and is thus widely used in various electronic industries. As advancements are made in the electronic industry, research on improving performance and reducing a size of a semiconductor device has continued.

A semiconductor device is manufactured by performing a plurality of manufacturing processes. If a slight error occurs in each manufacturing process, performance and productivity of the semiconductor device may be deteriorated. Accordingly, various sensors are applied to maintain a uniform process condition in the manufacturing process of the semiconductor device. However, an offset error may occur in a sensor as time passes. The offset error of the sensor may cause a difference in a final dimension of a portion included in the semiconductor device or in a property of the semiconductor device, which may reduce reliability and productivity of the semiconductor device.

### SUMMARY

Embodiments of the present disclosure provide a manufacturing apparatus of a semiconductor device capable of enhancing reliability and productivity of a semiconductor device.

According to embodiments of the present disclosure, a manufacturing apparatus of a semiconductor device is provided and includes: a wafer-type magnetic sensor including a wafer body portion and at least one measuring sensor at or in the wafer body portion; and a calibrator configured to perform an offset calibration of the at least one measuring sensor.

According to embodiments of the present disclosure, a manufacturing apparatus of a semiconductor device is provided and includes: a wafer-type magnetic sensor. The wafer-type magnetic sensor includes a wafer body portion; a measuring sensor at or in the wafer body portion; and a calibrator including a reference sensor, the calibrator configured to perform an offset calibration of the measuring sensor.

According to embodiments of the present disclosure, a manufacturing apparatus of a semiconductor device is provided and includes: a wafer-type magnetic sensor including a wafer body portion and at least one measuring sensor at or in the wafer body portion; and a calibrator configured to perform, during a manufacturing process of a semiconductor device by the manufacturing apparatus, an offset calibration of the at least one measuring sensor.

According to an embodiment of the present disclosure, an offset calibration of a measuring sensor included in a wafer-type magnetic sensor may be performed frequently by a calibrator without an addition apparatus or process. Thereby, the wafer-type magnetic sensor may be maintained in a zero-offset state, and thus, a manufacturing process of a semiconductor device may be performed under a uniform process condition. Accordingly, reliability and productivity of the semiconductor device may be enhanced.

### BRIEF DESCRIPTION OF DRAWINGS

FIG. 1 is a perspective view schematically illustrating a wafer-type magnetic sensor according to an embodiment.

FIG. 2 is a cross-sectional view taken along a line A-A′ and a line B-B′ of FIG. 1.

FIG. 3 is a block diagram schematically illustrating the wafer-type magnetic sensor illustrated in FIG. 1.

FIG. 4 schematically illustrates an example of a manufacturing apparatus of a semiconductor device to which a wafer-type magnetic sensor according to an embodiment is applied.

FIG. 5 is a flowchart schematically illustrating a calibration method of a wafer-type magnetic sensor according to an embodiment.

FIG. 6 is a flowchart illustrating the calibration method of the wafer-type magnetic sensor illustrated in FIG. 5.

FIG. 7 illustrates an offset calibration of a magnetic sensor.

FIG. 8 is a perspective view schematically illustrating a wafer-type magnetic sensor according to an embodiment.

FIG. 9 is a cross-sectional view taken along a line C-C′ and a line D-D′ of FIG. 8.

FIG. 10A is a schematic block diagram of the wafer-type magnetic sensor illustrated in FIG. 8.

FIG. 10B is a schematic block diagram of the wafer-type magnetic sensor illustrated in FIG. 8.

FIG. 11 is a flowchart illustrating a calibration method of a wafer-type magnetic sensor according to an embodiment.

FIG. 12 is a perspective view schematically illustrating an example of a manufacturing apparatus of a semiconductor device to which a wafer-type magnetic sensor according to an embodiment is applied.

FIG. 13 is a perspective view schematically illustrating the wafer-type magnetic sensor illustrated in FIG. 12.

FIG. 14 is a flowchart illustrating a calibration method of a wafer-type magnetic sensor according to an embodiment.

FIG. 15 is a perspective view schematically illustrating an example of a manufacturing apparatus of a semiconductor device to which a wafer-type magnetic sensor according to an embodiment is applied.

FIG. 16 schematically illustrates the manufacturing apparatus of the semiconductor device illustrated in FIG. 15.

FIG. 17 is a flowchart illustrating a calibration method of a wafer-type magnetic sensor according to an embodiment.

FIG. 18 is a flowchart illustrating a calibration method of a wafer-type magnetic sensor according to an embodiment.

### DETAILED DESCRIPTION

Non-limiting example embodiments of the present disclosure will be described more fully hereinafter with reference to the accompanying drawings for those skilled in the art to which the present disclosure pertains to easily practice embodiments of the present disclosure. Embodiments of the present disclosure may be implemented in various different forms and are not limited to the example embodiments provided herein.

A portion unrelated to the description may be omitted in order to clearly describe embodiments of the present disclosure, and the same or similar components are denoted by the same reference numeral throughout the present specification.

Further, since sizes and thicknesses of portions, regions, members, units, layers, films, etc. illustrated in the accompanying drawings may be arbitrarily illustrated for better understanding and convenience of explanation, the present disclosure is not limited to the illustrated sizes and thicknesses. In the drawings, thicknesses of portions, regions, members, units, layers, films, etc. may be enlarged or exaggerated for convenience of explanation.

It will be understood that when a component such as a layer, film, region, or substrate is referred to as being “on” another component, it may be directly on other component or an intervening component may also be present. In contrast, when a component is referred to as being “directly on” another component, there is no intervening component present. Further, when a component is referred to as being “on” or “above” a reference component, a component may be positioned on or below the reference component, and is not necessarily “on” or “above” the reference component toward an opposite direction of gravity.

In addition, unless explicitly described to the contrary, the word “comprise” (or “include”), and variations such as “comprises” (or “includes”) or “comprising” (or “including”), will be understood to imply the inclusion

Further, throughout the specification, a phrase “on a plane,” “in a plane,” “on a plan view,” or “in a plan view” may indicate a case where a portion is viewed from above or a top portion, and a phrase “on a cross-section” or “in a cross-section” may indicate when a cross-section taken along a vertical direction is viewed from a side.

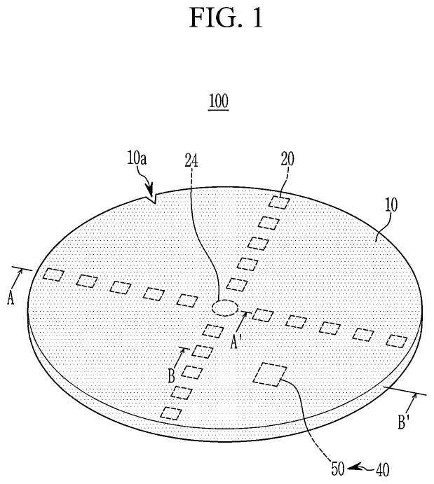

Hereinafter, with reference to FIG. 1 to FIG. 7, a wafer-type magnetic sensor 100 and a manufacturing apparatus of a semiconductor device including the same, and a calibration method of a wafer-type magnetic sensor 100 will be described in detail.

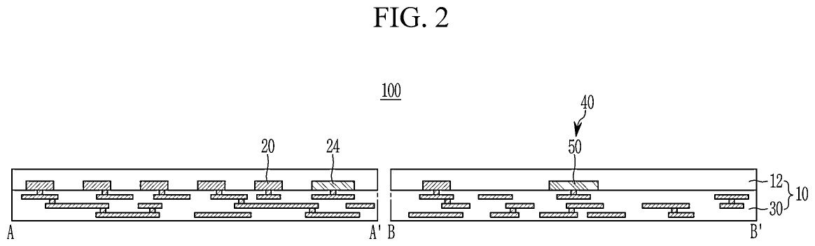

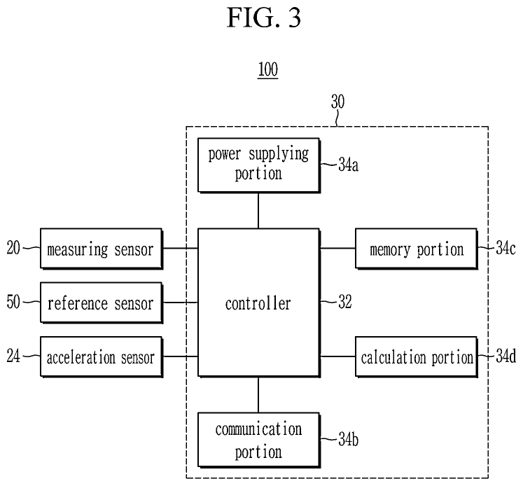

FIG. 1 is a perspective view schematically illustrating a wafer-type magnetic sensor 100 according to an embodiment. FIG. 2 is a cross-sectional view taken along a line A-A′ and a line B-B′ of FIG. 1. FIG. 3 is a block diagram schematically illustrating the wafer-type magnetic sensor 100 illustrated in FIG. 1. For simple illustration and a clear understanding, a wafer body portion 10, a measuring sensor 20, an acceleration sensor 24, and a reference sensor 50 of the wafer-type magnetic sensor 100 are mainly illustrated in FIG. 1, and a shape of a circuit portion 30 is schematically illustrated in FIG. 2.

Referring to FIG. 1 to FIG. 3, a wafer-type magnetic sensor 100 according to an embodiment may include a wafer body portion 10 having a wafer shape, a measuring sensor 20 at or in the wafer body portion 10, and a calibrator 40 configured to perform an offset calibration of the measuring sensor 20, and may further include a circuit portion 30 and an acceleration sensor 24. In an embodiment, the calibrator 40 may include a reference sensor 50.

The wafer body portion 10 may have a wafer shape or a circular plate shape similar to the wafer shape. The wafer body portion 10 may have a size or weight the same as or similar to a size or weight of a wafer. Thereby, in a manufacturing process of a semiconductor device, the wafer body portion 10 or the wafer-type magnetic sensor 100 may be treated or processed in the same way as the wafer. For example, the wafer-type magnetic sensor 100 may be transported to and entered in a manufacturing apparatus of a semiconductor device in the same way as the wafer. In the specification, a semiconductor device may refer to structures having various shapes in the manufacturing process of the semiconductor device. For example, the semiconductor device may refer to a wafer, a semiconductor substrate, a structure including one or a plurality of layers on a wafer or a semiconductor substrate, etc. The semiconductor device may be referred to as a semiconductor chip, a semiconductor apparatus, a semiconductor package, etc.

In FIG. 1, it is illustrated as an example that the wafer body portion 10 includes a notch 10a. A wafer may include a notch or a flat zone for an alignment of the wafer. The wafer body portion 10 or the wafer-type magnetic sensor 100 according to an embodiment may have the notch 10a having a size or a shape the same as a size or a shape of the notch of the wafer. However, embodiments of the present disclosure are not limited thereto. In some embodiments, the wafer body portion 10 or the wafer-type magnetic sensor 100 may have a flat zone having a size or a shape the same as a size or a shape of the flat zone of the wafer. A portion for the alignment of the wafer body portion 10 or the wafer-type magnetic sensor 100 may have any of various shapes or structures.

The measuring sensor 20 may be a sensor configured to measure a magnetic field to generate or collect measured magnetic field data. The measuring sensor 20 may measure a magnetic field of a manufacturing apparatus of a semiconductor device (e.g., a unit manufacturing apparatus) used in a manufacturing process of a semiconductor device. Here, the unit manufacturing apparatus may be a manufacturing apparatus of a semiconductor device that performs at least one process among a plurality of processes included in the manufacturing process of the semiconductor device.

The reference sensor 50 may be a calibration magnetic sensor that generates or provides reference magnetic field data (e.g., a reference value of a magnetic field or a true value of a magnetic field) for the offset calibration of the measuring sensor 20. For example, the reference sensor 50 may perform a self-calibration and maintain a zero-offset state to generate or provide the reference magnetic field data in the zero-offset state.

In an embodiment, the reference sensor 50 may be included in or provided on the wafer body portion 10. For example, the reference sensor 50 may be mounted on or embedded in the wafer body portion 10. For example, the reference sensor 50 may be mounted on or embedded in the wafer body portion 10 to have the same coordinate or direction vector as the measuring sensor 20. In some embodiments, coordinates or direction vectors of the measuring sensor 20 and the reference sensor 50 may be set or predetermined, and thus, the coordinates or the direction vectors of the measuring sensor 20 and the reference sensor 50 may be matched or aligned to each other by a coordinate matching calculation. Accordingly, an additional apparatus, process, etc., for matching or aligning the coordinates or the direction vectors of the measuring sensor 20 and the reference sensor 50 might not be needed.

In an embodiment, the reference sensor 50 may perform a self-calibration by using an earth magnetic field. For example, the reference sensor 50 may perform the self-calibration by using the earth magnetic field when a movement of the wafer-type magnetic sensor 100 exists, without an additional instruction. Further, when a calibration instruction is received from a controller 32, the reference sensor 50 may measure a magnetic field of a manufacturing apparatus of a semiconductor device and generate reference magnetic field data, and the measuring sensor 20 may measure the magnetic field of the manufacturing apparatus of the semiconductor device and generate measured magnetic field data. A calculation portion 34d may calculate a calibration parameter for the offset calibration of the measuring sensor 20 using the reference magnetic field data and the measured magnetic field data. The controller 32 may perform the offset calibration of the measuring sensor 20 according to the calibration parameter.

In an embodiment, the reference sensor 50 may have a signal-to-noise ratio (SNR) greater than a signal-to-noise ratio of the measuring sensor 20, and may be a high-precision magnetic sensor, compared to the measuring sensor 20. The measuring sensor 20 may measure a relatively large range of a magnetic field, and may have relatively low precision or a relatively low signal-to-noise ratio. Thus, the measuring sensor 20 may be a magnetic sensor that may be difficult to perform the self-calibration by using the earth magnetic field. The reference sensor 50 may have relatively high precision or a relatively high signal-to-noise ratio. Thus, the reference sensor 50 may be a magnetic sensor that is capable of performing the self-calibration by using the earth magnetic field.

For example, the measuring sensor 20 may measure a magnetic field ranging from about 100 times to about 500 times of the earth magnetic field, or a ratio of the signal-to-ratio (SNR) of the measuring sensor 20 to the SNR of the earth magnetic field may be about 0.5 to about 2.5. For example, the reference sensor 50 may measure the earth magnetic field, or a ratio of the SNR of the reference sensor 50 to the SNR of the earth magnetic field may be about 10 or more. For example, the reference sensor 50 may measure a magnetic field ranging from a magnetic field less than the earth magnetic field to a magnetic field greater than the earth magnetic field. That is, a minimum magnetic field measured by the reference sensor 50 may be less than the earth magnetic field, and a maximum magnetic field measured by the reference sensor 50 may be about 1 time or more the earth magnetic field. In the above range, the reference sensor 50 may have the SNR being capable of performing the self-calibration by using the earth magnetic field. However, embodiments of the present disclosure are not limited thereto. The range of the magnetic field measured by the measuring sensor 20 or the reference sensor 50 or the SNR of the measuring sensor 20 or the reference sensor 50 may be variously modified.

In an embodiment, by including the measuring sensor 20 and the reference sensor 50 together, the magnetic field of the manufacturing apparatus of the semiconductor device may be measured by using the measuring sensor 20 being suitable to measure the magnetic field of the manufacturing apparatus of the semiconductor device, and the offset calibration of the measuring sensor 20 may be performed by using the reference sensor 50. In an embodiment, the measuring sensor 20 may be provided in plural, and the reference sensor 50 may be provided in plural. A number of the measuring sensor 20 may be greater than a number of the reference sensor 50. The measuring sensor 20 may be provided in relatively large numbers to confirm a magnetic field distribution. It may be sufficient for the reference sensor 50 to provide the reference magnetic field data, and thus, the reference sensor 50 may be provided in a small number.

In FIG. 1, it is illustrated as an example that the measuring sensor 20 may be provided in plural (e.g., as a plurality of measuring sensors) in a first direction and in a second direction that intersects the first direction. Thereby, the magnetic field distribution may be effectively confirmed by the measuring sensor 20, and a space for the circuit portion 30 may be stably provided. However, the embodiments are not limited to a number, an arrangement, etc., of the measuring sensor 20.

The acceleration sensor 24 may be included in or be provided on the wafer body portion 10 to generate or provide acceleration data of the wafer-type magnetic sensor 100. A movement or position of the wafer-type magnetic sensor 100 may be detected by the acceleration sensor 24. The acceleration data may be considered together when the measured magnetic field data by the measuring sensor 20 or the reference magnetic field data by the reference sensor 50 is generated. Thereby, the precision of the measured magnetic field data or the reference magnetic field data may be enhanced. The acceleration sensor 24 may have any of various structures or types being capable of measuring acceleration.

For example, in a plan view, one acceleration sensor 24 may be at a center of the wafer body portion 10. However, embodiments of the present disclosure are not limited thereto. A position, a number, etc., of the acceleration sensor 24 may be variously modified. For example, in a plan view, the acceleration sensor 24 may be at a region other than the center of the wafer body portion 10, or a plurality of acceleration sensors 24 may be provided.

The circuit portion 30 may include any of various members that control an operation of the wafer-type magnetic sensor 100. For example, the circuit portion 30 may include or be formed of a printed circuit board (PCB) including any of various circuit elements, wirings, etc., but embodiments of the present disclosure are not limited thereto.

In an embodiment, the circuit portion 30 may include the controller 32, a power supplier 34a, a communication interface 34b, a memory 34c, the calculation portion 34d, etc.

The power supplier 34a may supply power to the wafer-type magnetic sensor 100, and may have any of various structures or types. For example, the power supplier 34a may include a battery.

The communication interface 34b may have any of various structures or types for a wireless communication between the wafer-type magnetic sensor 100 and an external circuit (e.g., an integrated controller of the manufacturing apparatus of the semiconductor device). According to embodiments, the communication interface 34b may include at least one from among, and any combination of, a cable, a digital modem, a radio frequency (RF) modem, an antenna circuit, a WiFi chip, and related software and/or firmware.

The memory 34c may store data for controlling an operation of the wafer-type magnetic sensor 100. For example, the memory 34c may store the measured magnetic field data provided from the measuring sensor 20, the reference magnetic field data provided from the reference sensor 50, the acceleration data provided from the acceleration sensor 24, the calibration parameter calculated by the calculation portion 34d, etc.

The calculation portion 34d may calculate the calibration parameter for the self-calibration of the reference sensor 50 by using the reference magnetic field data provided from the reference sensor 50, or may calculate the calibration parameter for the offset calibration of the measuring sensor 20 by using the measured magnetic field data provided from the measuring sensor 20 and the reference magnetic field data provided from the reference sensor 50.

The controller 32 may control operations of the power supplier 34a, the communication interface 34b, the memory 34c, the calculation portion 34d, the measuring sensor 20, the reference sensor 50, and the acceleration sensor 24. The controller 32 may implement various modes, such as, standby mode, self-calibration mode, measuring mode, calibration mode, etc.

In FIG. 2, it is illustrated as an example that the wafer body portion 10 includes the circuit portion 30, and a resin layer 12 covering the measuring sensor 20, the acceleration sensor 24, and the reference sensor 50 on the circuit portion 30. By including the resin layer 12, the wafer body portion 10 may be easily formed to have a wafer shape without affecting a magnetic field measurement. However, the embodiments are not limited to a material or a structure of the wafer body portion 10, and the wafer body portion 10 may have any of various materials or structures.

In a modified embodiment, at least one from among the circuit portion 30, the measuring sensor 20, the acceleration sensor 24, and the reference sensor 50 may be on the wafer body portion 10. Here, the wafer body portion 10 may include a semiconductor substrate (e.g., a wafer), a resin, etc. In a modified embodiment, the wafer body portion 10 may include the resin layer 12 entirely surrounding the circuit portion 30, the measuring sensor 20, the acceleration sensor 24, and the reference sensor 50. Other various modifications are also possible.

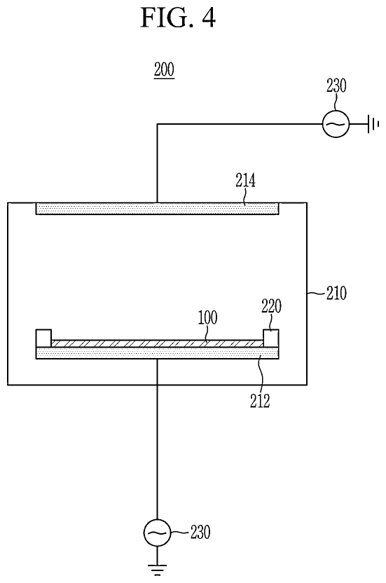

The wafer-type magnetic sensor 100 may be applied to or included in the manufacturing apparatus of the semiconductor device (e.g., the unit manufacturing apparatus). Referring to FIG. 4, an example of a manufacturing apparatus of a semiconductor device to which the wafer-type magnetic sensor 100, according to an embodiment, is applied will be described.

FIG. 4 schematically illustrates an example of a manufacturing apparatus of a semiconductor device to which a wafer-type magnetic sensor 100, according to an embodiment, is applied.

Referring to FIG. 4, in an embodiment, a manufacturing apparatus of a semiconductor device may be a plasma etching apparatus 200. The plasma etching apparatus 200 may include a chamber 210, a first electrode 212, a second electrode 214, a focus ring 220, a power portion 230, etc.

The chamber 210 may include an inlet portion through which gas for plasma generation is supplied, and an outlet portion through which unprocessed gas is discharged after an etching process is completed. Plasma may be generated from the gas supplied into the chamber 210 when power is applied to the first electrode 212 and the second electrode 214.

A partial portion of a semiconductor device or a wafer on the first electrode 212 may be etched by the generated plasma. The first electrode 212 may act as a kind of a support or a chuck on which the semiconductor device is disposed. In FIG. 4, it is illustrated as an example that the first electrode 212 and the second electrode 214 face each other, but a position, a shape, etc., of the first electrode 212 and the second electrode 214 may be variously modified.

The power portion 230 may apply the power to the first electrode 212 and the second electrode 214, and the focus ring 220 may uniformly distribute the plasma to the semiconductor device or the wafer on the first electrode 212. The wafer-type magnetic sensor 100 may measure a magnetic field of the plasma etching apparatus 200 in a state that the wafer-type magnetic sensor 100 is on the first electrode 212, like the semiconductor device. However, embodiments of the present disclosure are not limited thereto. A position of the wafer-type magnetic sensor 100 that measures the magnetic field in the plasma etching apparatus 200 may be variously modified.

The plasma etching apparatus 200 may be affected by a magnetic field. For example, an etch rate of the semiconductor device or the wafer by an etching process performed in the plasma etching apparatus 200 may be varied by the magnetic field. The wafer-type magnetic sensor 100 according to the embodiment may be applied to the plasma etching apparatus 200 and measure the magnetic field of the plasma etching apparatus 200. Thereby, the magnetic field of the plasma etching apparatus 200 may be uniformly maintained by using the measured magnetic field data. Accordingly, the etch rate by the etching process performed in the plasma etching apparatus 200 may be uniformly maintained.

As such, the wafer-type magnetic sensor 100 may be applied to or included in the manufacturing apparatus of the semiconductor device affected by the magnetic field, and thus, the wafer-type magnetic sensor 100 may measure the magnetic field of the manufacturing apparatus of the semiconductor device or the magnetic field in the manufacturing process of the semiconductor device. In the description, the manufacturing apparatus of the semiconductor device is the plasma etching apparatus 200, but embodiments of the present disclosure are not limited thereto. That is, the wafer-type magnetic sensor 100 according to an embodiment may measure a magnetic field of a manufacturing apparatus of a semiconductor device using a magnetic field or measure a magnetic field in a manufacturing apparatus of a semiconductor device where a process condition or a property of a final structure may be varied by a magnetic field.

As such, the magnetic field of the manufacturing apparatus of the semiconductor device may be measured by using the wafer-type magnetic sensor 100. Accordingly, an additional apparatus, a chamber, etc., for measuring the magnetic field might not be needed and thus equipment burden and space burden may be minimized in the manufacturing process of the semiconductor device.

In the manufacturing apparatus of the semiconductor device or the wafer-type magnetic sensor 100 according to the embodiment, the offset calibration of the measuring sensor 20 may be performed frequently by the calibrator 40 without an additional apparatus or process. Thereby, reliability and productivity of the semiconductor device may be enhanced. Accordingly, deterioration of reliability and productivity of the semiconductor device, caused by the offset of a measuring sensor that may be generated as time passes, may be prevented or suppressed.

In an embodiment, the calibrator 40 may include the reference sensor 50 provided on (e.g., embedded in) the wafer-type magnetic sensor 100, thereby simplifying a structure of the calibrator 40. In this instance, the reference sensor 50 may perform the self-calibration by using the earth magnetic field and may be maintained in the zero-offset state without applying an additional magnetic field.

On the other hand, in a comparative embodiment not including a calibrator for an offset calibration of a measuring sensor, an additional apparatus, a process, etc., for a calibration of a wafer-type magnetic sensor may be required. For example, in a state that a magnetic field is applied to a wafer-type magnetic sensor, the wafer-type magnetic sensor rotates 360 degrees to perform an offset calibration of a measuring sensor. In this case, a magnetic-field applying apparatus having a large size (e.g., a coil with a diameter of 1 m or more) is required to apply the magnetic field to the wafer-type magnetic sensor. Accordingly, it may be difficult to be applied to a line performing a manufacturing process of a semiconductor device. Further, the offset calibration process is performed in a separate apparatus, and thus, additional process time for the offset calibration process is required and the offset calibration process is difficult to be performed frequently. In addition, there is a risk of a damage of the wafer-type magnetic sensor during the 360 degree rotation of the wafer-type magnetic sensor. In a comparative embodiment, an offset calibration of a wafer-type magnetic sensor is in a zero gauss chamber to perform an offset calibration. In this case, the zero gauss chamber having a relatively large size is required. Furthermore, the offset calibration process is performed in the separate zero gauss chamber, and thus, additional process time for the offset calibration process is required and the offset calibration process is difficult to be performed frequently.

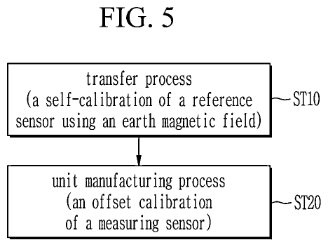

Referring to FIG. 5 to FIG. 7 together with FIG. 1 to FIG. 3, a calibration method of a wafer-type magnetic sensor 100 according to an embodiment will be described. The calibration method of the wafer-type magnetic sensor 100 according to the embodiment may be performed in a manufacturing process of a semiconductor device.

FIG. 5 is a flowchart schematically illustrating a calibration method of a wafer-type magnetic sensor 100 according to an embodiment.

Referring to FIG. 1 to FIG. 3, and FIG. 5, in a calibration method of a wafer-type magnetic sensor 100 according to the embodiment, a self-calibration of a reference sensor 50 may be performed using an earth magnetic field in a transfer process ST10, and an offset calibration of a measuring sensor 20 may be performed in a unit manufacturing process ST20.

In the transfer process ST10, a semiconductor device, a wafer, or a wafer-type magnetic sensor 100 may be transferred in a manufacturing process of a semiconductor device. In the transfer process ST10 according to an embodiment, the semiconductor device, the wafer, or the wafer-type magnetic sensor 100 may be transferred to a unit manufacturing apparatus through a transfer apparatus or an automation logistics system according to a control of an integrated controller or an automation system. For example, the transfer apparatus may include at least one from among a transfer robot, an equipment front end module (EFEM), or an overhead hoist transport (OHT).

The unit manufacturing process ST20 may be a manufacturing process performed in a unit manufacturing apparatus that performs at least one process among a plurality of processes included in the manufacturing process of the semiconductor device. For example, the unit manufacturing apparatus may be a photolithography apparatus, an etching apparatus, a deposition apparatus, etc., and the unit manufacturing process may be a photolithography process, an etching process, a deposition process, etc.

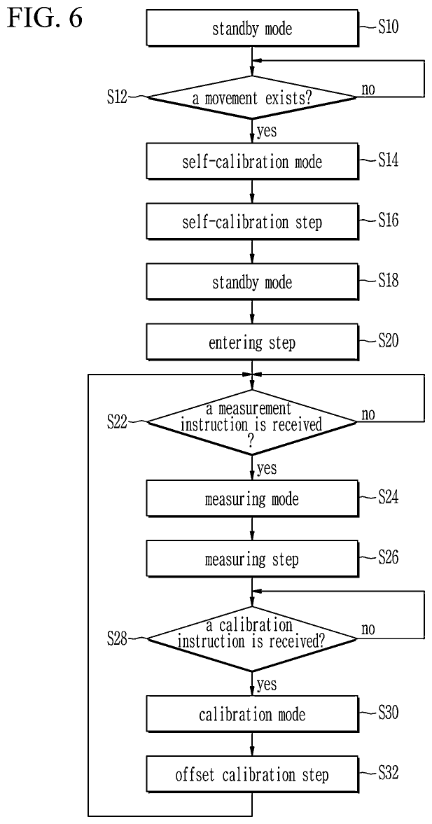

FIG. 6 is a flowchart illustrating the calibration method of the wafer-type magnetic sensor 100 illustrated in FIG. 5.

In an embodiment, the transfer process ST10 may include a standby mode S10, a movement determination step S12 of determining whether a movement of a wafer-type magnetic sensor 100 exists, a self-calibration mode S14, a self-calibration step S16 of performing a self-calibration of the reference sensor 50, a standby mode S18, and an entering step S20 of entering into the unit manufacturing apparatus. The unit manufacturing process ST20 may include a measurement-instruction determination step S22 of determining whether a measurement instruction is received, a measuring mode S24, a measuring step S26 of measuring a magnetic field by a measuring sensor 20, a calibration-instruction determination step S28 of determining whether a calibration instruction is received, a calibration mode S30, and an offset calibration step S32 of performing an offset calibration of the measuring sensor 20.

First, power may be applied to the wafer-type magnetic sensor 100, and the wafer-type magnetic sensor 100 may be maintained in the standby mode S10. In the standby mode S10, the wafer-type magnetic sensor 100 may be maintained in a ready state so that the wafer-type magnetic sensor 100 performs an operation according to the operation instruction of a controller 32.

For example, when there is a power supply instruction, a power supplier 34a may supply the power to the wafer-type magnetic sensor 100. The power supply instruction may be generated by a controller 32, or may be delivered from an integrated controller of a manufacturing apparatus of a semiconductor device to the controller 32 through a communication interface 34b.

In the standby mode S10, the movement determination step S12 of determining whether the movement of the wafer-type magnetic sensor 100 exists may be performed. Here, the movement of the wafer-type magnetic sensor 100 may refer to a movement being capable of performing a self-calibration of a reference sensor 50 (e.g., the self-calibration of the reference sensor 50 by using an earth magnetic field). For example, the controller 32 may determine whether the movement of the wafer-type magnetic sensor 100 exists by using acceleration data generated by an acceleration sensor 24.

If the movement of the wafer-type magnetic sensor 100 is determined to not exist, the wafer-type magnetic sensor 100 is maintained in the standby mode S10 and whether the movement of the wafer-type magnetic sensor 100 exists may be determined periodically.

If the movement of the wafer-type magnetic sensor 100 exists, the wafer-type magnetic sensor 100 may be converted to the self-calibration mode S14. In the self-calibration mode S14, the self-calibration step S16 of performing the self-calibration of the reference sensor 50 may be performed. That is, the self-calibration of the reference sensor 50 may be performed when the movement of the wafer-type magnetic sensor 100 exists, without an additional instruction. Thereby, the reference sensor 50 may be maintained in a zero-offset state.

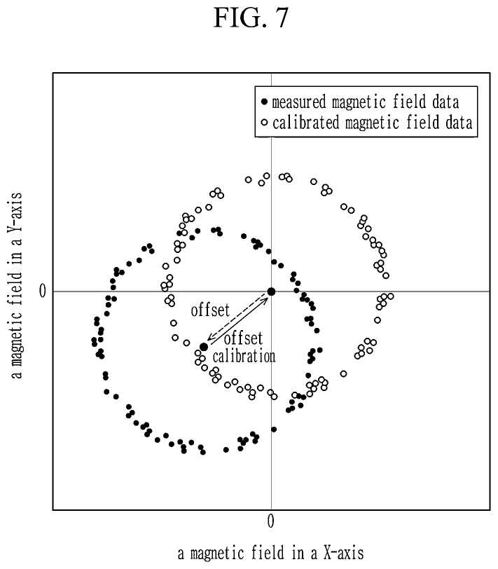

An offset calibration of a magnetic sensor will be described in detail with reference to FIG. 7, and then, the self-calibration of the reference sensor 50 will be described in detail. FIG. 7 illustrates an offset calibration of a magnetic sensor.

Referring to FIG. 7, a magnetic field measured by a magnetic sensor has a vector, and magnetic field data having a circular shape may be obtained in an xy plane, a yz plane, and an xz plane when magnetic field data in various directions is obtained by moving (e.g., rotating 360 degrees) a magnetic sensor in an area where a constant magnetic field exists. FIG. 7 illustrates the magnetic field data in the xy plane and illustrates an example that the magnetic field data has an overall circular shape to clearly explain an offset calibration.

When a separate magnetic field is not applied and there is no offset of the magnetic sensor, a center point of the measured magnetic field data is at a zero (0) point. If there is an offset of the magnetic sensor, a center point of the measured magnetic field data may be offset from the zero (0) point, as illustrated by a dotted line in FIG. 7. An offset calibration that moves the center point of the measured magnetic field data to the zero (0) point by using a calibration parameter, as illustrated by a solid line in FIG. 7, may be performed.

The self-calibration of the reference sensor 50 may be performed by using a principal of the offset calibration of the magnetic sensor. In an embodiment, in the self-calibration step S16, the self-calibration of the reference sensor 50 may be performed by using the earth magnetic field.

More particularly, in the self-calibration step S16, measured magnetic field data may be obtained by the reference sensor 50 using the earth magnetic field when the movement of the wafer-type magnetic sensor 100 exists, and an offset (e.g., each offset in an x-axis, a y-axis, and a z-axis) of a center point of the measured magnetic field data from a zero (0) point may be determined. In the self-calibration of the reference sensor 50, the center point of the measured magnetic field data may be converted to the zero (0) point by using a calibration parameter (e.g., each calibration parameter in the x-axis, the y-axis, and the z-axis).

When the self-calibration step S16 of performing the self-calibration of the reference sensor 50 is completed, a completion signal may be provided to the controller 32. The controller 32 may convert the wafer-type magnetic sensor 100 to the standby mode S18. The standby mode S18 is maintained until the wafer-type magnetic sensor 100 is converted to the measuring mode S24 or the calibration mode S30 by receiving a measurement instruction or a calibration instruction after the entering step S20 of entering in the unit manufacturing apparatus.

In an embodiment, the self-calibration of the reference sensor 50 may be performed by using the movement of the wafer-type magnetic sensor 100 in the transfer process ST10. The wafer-type magnetic sensor 100 may move in the x-axis, the y-axis, and/or the z-axis in the transfer process ST10, and thus, the measured magnetic field data including a large amount of data may be obtained by the movement of the wafer-type magnetic sensor 100. Even if the reference sensor 50 moves in the x-axis, the y-axis, and/or the z-axis without rotating 360 degrees, the center point of the measured magnetic field data may be confirmed by using the acceleration data generated or provided from the acceleration sensor 24 together or by the reference sensor 50 having the high precision. As such, the self-calibration of the reference sensor 50 may be performed as a part of the transfer process ST10, and thus, an additional process or apparatus for the self-calibration of the reference sensor 50 might not be needed.

After the entering step S20 of entering the wafer-type magnetic sensor 100 into the unit manufacturing apparatus, the measurement-instruction determination step S22 of determining whether the measurement instruction is received may be performed. Based on the measurement instruction being received from the controller 32, the wafer-type magnetic sensor 100 may be converted to the measuring mode S24.

In the measuring mode S24, the measuring sensor 20 may measure a magnetic field of the unit manufacturing apparatus, generate measured magnetic field data, and provide the measured magnetic field data to the controller 32 or a memory 34c. The reference sensor 50 may wait until the calibration instruction is received.

After the entering step S20 of entering the wafer-type magnetic sensor 100 into the unit manufacturing apparatus, the calibration-instruction determination step S28 of determining whether the calibration instruction is received or not may be performed. When the calibration instruction is received from the controller 32, the wafer-type magnetic sensor 100 may be converted to the calibration mode S30.

In the calibration mode S30, the offset calibration step S32 of performing the offset calibration of the measuring sensor 20 may be performed by using reference magnetic field data generated from the reference sensor 50. The measuring sensor 20 may measure the magnetic field of the unit manufacturing apparatus, generate the measured magnetic field data, and provide the measured magnetic field data to the controller 32 or the memory 34c. The reference sensor 50 may measure the magnetic field of the unit manufacturing apparatus, generate the reference magnetic field data, and provide the reference magnetic field data to the controller 32 or the memory 34c. A calculation portion 34d may calculate a calibration parameter by using the measured magnetic field data and the reference magnetic field data. The offset calibration step S32 of performing the offset calibration of the measuring sensor 20 may be performed by using the calibration parameter.

When the offset calibration of the measuring sensor 20 is complete, a completion signal may be provided to the controller 32. The controller 32 may convert the wafer-type magnetic sensor 100 to a standby mode. The wafer-type magnetic sensor 100 may wait until the measurement instruction or the calibration instruction is received.

According to embodiments, when a termination instruction exists (e.g., is received) during the unit manufacturing process ST20, a power supply to the wafer-type magnetic sensor 100 through the power supplier 34a may stop and thus an operation of the wafer-type magnetic sensor 100 may stop.

In FIG. 6, it is illustrated as an example that the calibration-instruction determination step S28, the calibration mode S30, and the offset calibration step S32 are performed after the measurement-instruction determination step S22, the measuring mode S24, and the measuring step S26. In some embodiments, the measurement-instruction determination step S22, the measuring mode S24, and the measuring step S26 may be performed after the calibration-instruction determination step S28, the calibration mode S30, and the offset calibration step S32.

In an embodiment, in the unit manufacturing process ST20, the offset calibration of the measuring sensor 20 may be performed based on the calibration instruction. In this instance, the offset calibration of the measuring sensor 20 may be performed by using a magnetic field (e.g., an earth magnetic field) to which the measuring sensor 20 and the reference sensor 50 are commonly exposed or a magnetic field used in the unit manufacturing apparatus.

Accordingly, the offset calibration of the measuring sensor 20 may be frequently performed without an additional apparatus or process. That is, additional processes (e.g., a process of transferring the wafer-type magnetic sensor 100 to an additional apparatus and a process of performing an offset calibration in the additional apparatus) for the offset calibration of the measuring sensor 20 might not be needed. Accordingly, a process for the offset calibration of the measuring sensor 20 may be simplified and calibration time may be minimized.

In the calibration method of the wafer-type magnetic sensor 100 according to an embodiment, the wafer-type magnetic sensor 100 may be maintained in the zero-offset state, and thus, the manufacturing process of the semiconductor device may be performed under a uniform process condition (e.g., a uniform magnetic field). Accordingly, reliability and productivity of the semiconductor device may be enhanced.

In an embodiment, the transfer process ST10 of performing the self-calibration of the reference sensor 50 and the unit manufacturing process ST20 of performing the offset calibration of the measuring sensor 20 may be performed by a transfer apparatus or an automation logistics system (e.g., by at least one processor of the transfer apparatus or of the automation logistics system). Thereby, an entire process that performs the offset calibration of the measuring sensor 20 included in the wafer-type magnetic sensor 100 may be automatized or unmanned, thereby enhancing productivity.

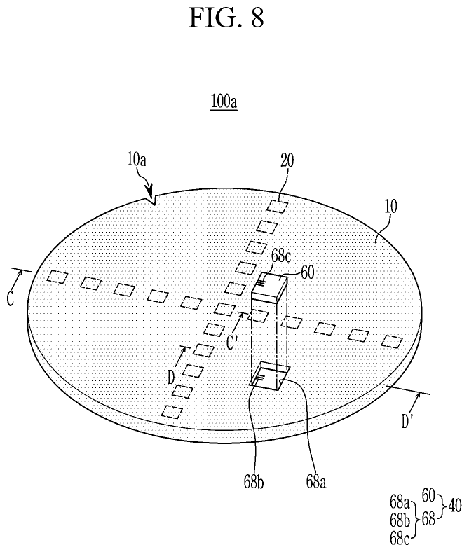

Referring to FIG. 8 to FIG. 18, a wafer-type magnetic sensor and a manufacturing apparatus of a semiconductor device including the same, and a calibration method of a wafer-type magnetic sensor according to an embodiment will be described in detail. To the extent that an element is not described in detail below, it should be understood that the element is at least similar to a corresponding element that has been described elsewhere within the present disclosure. Accordingly, repeated descriptions may be omitted below.

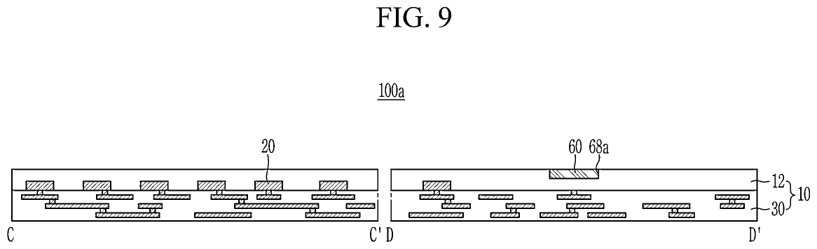

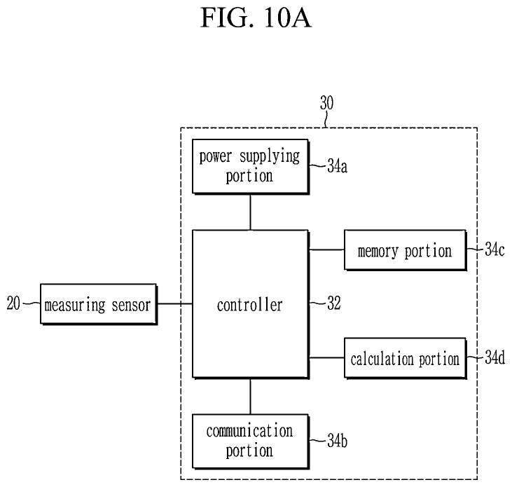

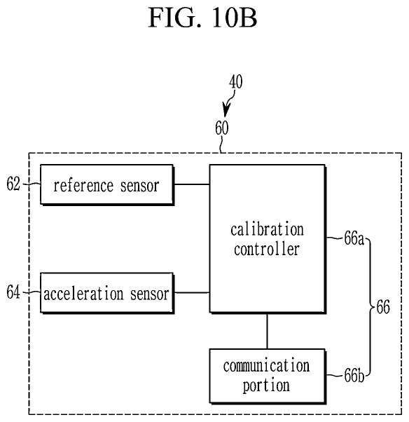

FIG. 8 is a perspective view schematically illustrating a wafer-type magnetic sensor 100a according to an embodiment. FIG. 9 is a cross-sectional view taken along a line C-C′ and a line D-D′ of FIG. 8. FIG. 10A and FIG. 10B are schematic block diagrams of the wafer-type magnetic sensor 100a illustrated in FIG. 8. For simple illustration and a clear understanding, a wafer body portion 10 and a measuring sensor 20 of the wafer-type magnetic sensor 100a are mainly illustrated in FIG. 8, and a shape of a circuit portion 30 is schematically illustrated in FIG. 9. FIG. 10A is a block diagram of the wafer-type magnetic sensor 100a, except for a calibrator 40. FIG. 10B is a block diagram of the calibrator 40.

Referring to FIG. 8, FIG. 9, FIG. 10A, and FIG. 10B, a wafer-type magnetic sensor 100a according to an embodiment may include a wafer body portion 10 having a wafer shape, a measuring sensor 20 at or in the wafer body portion 10, and a calibrator 40 configured to perform an offset calibration of the measuring sensor 20, and may further include a circuit portion 30. In an embodiment, the calibrator 40 may include a calibration member 60 including a reference sensor 62, and may further include a coordinate alignment portion 68 for a coordinate alignment of the reference sensor 62 and the measuring sensor 20.

The circuit portion 30 may include any of various portions that control an operation of the wafer-type magnetic sensor 100. For example, the circuit portion 30 may include or be formed of a printed circuit board including any of various circuit elements, wirings, etc., but embodiments are not limited thereto. In an embodiment, the circuit portion 30 may include a controller 32, a power supplier 34a, a communication interface 34b, a memory 34c, a calculation portion 34d, etc.

In an embodiment, the calibration member 60 may be a separated member from the wafer body portion 10 and may be separately provided from the wafer body portion 10. The calibration member 60 may be separably, removably, or detachably fixed to the wafer body portion 10. For example, the calibration member 60 may be detachable to the wafer body portion 10. In FIG. 8 to FIG. 10, it is illustrated as an example that the calibration member 60 is directly fixed to the wafer body portion 10, but embodiments of the present disclosure are not limited thereto. The calibration member 60 might not be directly fixed to the wafer body portion 10 or might not be in contact with the wafer body portion 10. Other various modifications are also possible.

In an embodiment, the calibration member 60 may include a reference sensor 62, an acceleration sensor 64, and a calibration circuit portion 66. The calibration circuit portion 66 may include a calibration controller 66a and a communication interface 66b. According to embodiments, the communication interface 66b may include at least one from among, and any combination of, a cable, a digital modem, a radio frequency (RF) modem, an antenna circuit, a WiFi chip, and related software and/or firmware.

The reference sensor 62 may be a calibration magnetic sensor that generates or provides reference magnetic field data for an offset calibration of the measuring sensor 20. For example, the reference sensor 62 may perform a self-calibration and maintain a zero-offset state to generate or provide the reference magnetic field data in the zero-offset state. For example, the reference sensor 62 may be mounted on or embedded in the calibration member 60.

The acceleration sensor 64 may be included in or be provided on the calibration member 60 to generate or provide acceleration data of the calibration member 60. A movement or position of the calibration member 60 may be detected by the acceleration sensor 64. The acceleration data may be considered together when the measured magnetic field data by the measuring sensor 20 or the reference magnetic field data by the reference sensor 62 is generated. Thereby, the precision of the measured magnetic field data or the reference magnetic field data may be enhanced. The acceleration sensor 64 may have any of various structures or types being capable of measuring acceleration.

According to embodiments, the acceleration sensor 64 is included in the calibration member 60 while an acceleration sensor is not included in the wafer body portion 10. However, embodiments of the present disclosure are not limited thereto. The wafer body portion 10 may include an acceleration sensor, each of the wafer body portion 10 and the calibration member 60 may include an acceleration sensor, or the calibration member 60 might not include the acceleration sensor 64.

The calibration controller 66a of the calibration circuit portion 66 may control an operation the communication interface 66b, the reference sensor 62, and the acceleration sensor 64 included in the calibration member 60. The communication interface 66b of the calibration circuit portion 66 may have any of various structures or types for a wireless communication with a communication interface 34b of a circuit portion 30 and/or an integrated controller of a manufacturing apparatus of a semiconductor device. The calibration circuit portion 66 may further include a memory, a calculation portion, etc.

In an embodiment, the self-calibration of the reference sensor 62 may be performed by the calibration circuit portion 66, and the offset calibration of the measuring sensor 20 may be performed by at least one from among the calibration circuit portion 66 and the circuit portion 30. For example, the calibration circuit portion 66 may calculate a calibration parameter for the self-calibration of the reference sensor 62 by using the reference magnetic field data provided from the reference sensor 62. At least one from among the calibration circuit portion 66 and the circuit portion 30 may perform a coordinate matching calculation for the coordinate alignment by using coordinates of the measuring sensor 20 and the reference sensor 62. At least one from among the calibration circuit portion 66 and the circuit portion 30 may calculate a calibration parameter for the offset calibration of the measuring sensor 20 by using measured magnetic field data provided from the measuring sensor 20 and reference magnetic field data provided from the reference sensor 62.

According to embodiments, the calibration circuit portion 66 includes the calibration controller 66a and the communication interface 66b. However, embodiments of the present disclosure are not limited thereto. The calibration circuit portion 66 may further include the memory, the calculation portion, or other portions as described above, or the calibration circuit portion 66 might not include a part of the calibration controller 66a and the communication interface 66b.

In an embodiment, the coordinate alignment portion 68 may include a guide structure 68a for the coordinate alignment of the reference sensor 62. The coordinate alignment portion 68 may be included in the wafer body portion 10. For example, the guide structure 68a may include or be formed of a recess, a concave, a groove, a protruding portion provided on or included in the wafer body portion 10, or may include or be formed of an additional structure attached to or mounted on the coordinate alignment portion 68.

For example, the reference sensor 62 may be mounted on or fixed to the wafer body portion 10 to have the same coordinate or direction vector as the measuring sensor 20 through the coordinate alignment portion 68. In some embodiments, coordinates or direction vectors of the measuring sensor 20 and the reference sensor 62 may be set or predetermined by the coordinate alignment portion 68, and thus, the coordinates or the direction vectors of the measuring sensor 20 and the reference sensor 62 may be matched or aligned each other by a coordinate matching calculation. Accordingly, an additional apparatus, process, etc., for matching or aligning the coordinates or the direction vectors of the measuring sensor 20 and the reference sensor 62 might not be needed.

According to embodiments, the coordinate alignment portion 68 includes the guide structure 68a. However, embodiments of the present disclosure are not limited thereto.

In some embodiments, a fixing structure of fixing the calibration member 60 to the wafer body portion 10 and another structure for the coordinate alignment of the reference sensor 62 included in the calibration member 60 and the measuring sensor 20 may be included.

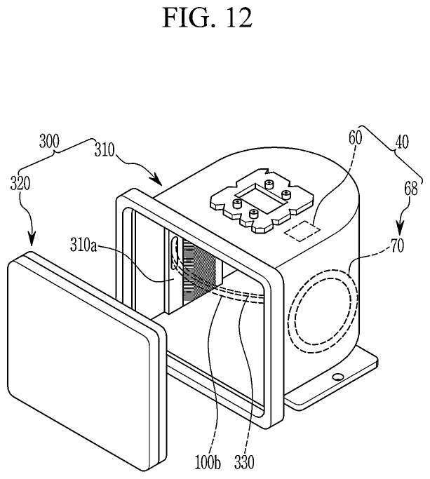

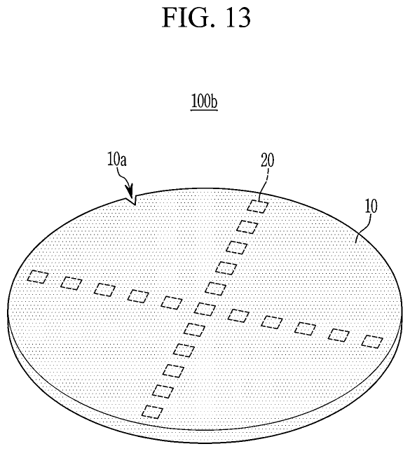

In some embodiments, the coordinate alignment portion 68 may include a sensor, a member (e.g., a magnetic-field applying member), a structure, a portion, etc., for the coordinate alignment of the reference sensor 62 and the measuring sensor 20. For example, the sensor for the coordinate alignment may be a vision sensor. Sensor directions of the reference sensor 62 and the measuring sensor 20 may be detected by the vision sensor, and the sensor directions of the reference sensor 62 and the measuring sensor 20 may be used for the coordinate alignment of the reference sensor 62 and the measuring sensor 20. The sensor for the coordinate alignment (e.g., the vision sensor) may be provided on the wafer body portion 10 or be fixed to the wafer body portion 10, or may be at a position spaced apart from the wafer body portion 10. The magnetic-field applying member may be provided on the wafer body portion 10 or be fixed to the wafer body portion 10, or may be at a position spaced apart from the wafer body portion 10. The coordinate alignment using the magnetic-field applying member may be referred later with reference to FIG. 12 and FIG. 13.

In FIG. 8, it is illustrated as an example that the coordinate alignment portion 68 includes alignment marks (e.g., a first alignment mark 68b and a second alignment mark 68c). The alignment marks may include a first alignment mark 68b provided on the wafer body portion 10, and a second alignment mark 68c provided on the calibration member 60. The calibration member 60 may be attached or fixed to the wafer body portion 10 so that the calibration member 60 has a predetermined direction using the first alignment mark 68b and the second alignment mark 68c. However, embodiments of the present disclosure are not limited thereto. The coordinate alignment portion 68 might not include the alignment marks, or any of various structures other than the alignment marks may be applied for the alignment.

The calibration member 60 according to an embodiment may have a portable size. For example, the calibration member 60 may have a box shape with a width of about 10 cm or less, a length of about 10 cm or less, and a height of about 10 cm or less (e.g., a width of about 5 cm or less, a length of about 5 cm or less, and a height of about 5 cm or less). The offset calibration of the measuring sensor 20 may be performed without equipment burden and space burden. However, embodiments of the present disclosure are not limited thereto. A size, a shape, etc., of the calibration member 60 may be variously modified.

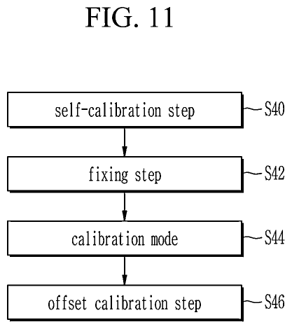

The wafer-type magnetic sensor 100a according to an embodiment may perform the self-calibration of the reference sensor 62 in a state that the calibration member 60 is separated from the wafer body portion 10 when the offset calibration of the measuring sensor 20 is not required. The calibration member 60 may be attached or fixed to the wafer body portion 10 and the offset calibration of the measuring sensor 20 may be performed when the offset calibration of the measuring sensor 20 is required. The self-calibration of the reference sensor 62 and the offset calibration of the measuring sensor 20 will be described later in more detail with reference to FIG. 11.

The wafer-type magnetic sensor 100a may be applied to or included in a manufacturing apparatus of a semiconductor device. That is, the wafer-type magnetic sensor 100a according to an embodiment may measure a magnetic field of a manufacturing apparatus of a semiconductor device using a magnetic field or measure a magnetic field in a manufacturing apparatus of a semiconductor device where a process condition or a property of a final structure may be varied by a magnetic field.

Referring to FIG. 11 together with FIG. 8 to FIG. 10, a calibration method of a wafer-type magnetic sensor 100a according to an embodiment will be described. The calibration method of the wafer-type magnetic sensor 100a according to the embodiment may be performed in a manufacturing process of a semiconductor device.

FIG. 11 is a flowchart illustrating a calibration method of a wafer-type magnetic sensor 100a according to an embodiment.

Referring to FIG. 8 to FIG. 11, in an embodiment, a calibration method of a wafer-type magnetic sensor 100a may include a self-calibration step S40 of performing a self-calibration of a reference sensor 62 included in a calibration member 60, a fixing step S42 of fixing the calibration member 60 to a wafer body portion 10, a calibration mode S44, and an offset calibration step S46 of performing an offset calibration of the measuring sensor 20.

Here, the self-calibration step S40 of performing the self-calibration of the reference sensor 62 may be performed in a transfer process or a unit manufacturing process in a manufacturing process of a semiconductor device, or may be performed in a process separately performed from the transfer process or the unit manufacturing process in the manufacturing process of the semiconductor device. In an embodiment, the calibration member 60 including the reference sensor 62 may be separable, removable, or detachable from the wafer body portion 10, and thus, the self-calibration step S40 of performing the self-calibration of the reference sensor 62 may be freely performed in any of various processes. The offset calibration step S46 of performing the offset calibration of the measuring sensor 20 may be performed in the transfer process or the unit manufacturing process in the manufacturing process of the semiconductor device, or may be performed in a process separately performed from the transfer process or the unit manufacturing process in the manufacturing process of the semiconductor device.

In an embodiment, the reference sensor 62 may be a sensor being capable of performing a self-calibration by using an earth magnetic field, as the reference sensor 50 described in an embodiment with reference to FIG. 1 to FIG. 7. Unless otherwise described, the description regarding the reference sensor 50 with reference to FIG. 1 to FIG. 7 may be applied to the reference sensor 62 being capable of performing the self-calibration by using the earth magnetic field and a self-calibration using the reference sensor 62.

In some embodiments, the self-calibration of the reference sensor 62 may be performed by using a magnetic field data obtained in a state that an additional magnetic field is applied to the calibration member 60. Any of various methods may be applied to the method for applying the magnetic field to the calibration member 60.

For example, a magnetic-field applying member (e.g., a coil) may be embedded in the calibration member 60. Thereby, magnetic field data may be obtained in a state the magnetic-field applying member embedded in the calibration member 60 applies a magnetic field to the reference sensor 62, and the self-calibration step S40 of performing the self-calibration of the reference sensor 62 may be performed by using the magnetic field data. For example, the reference sensor 62 may measure magnetic field in a state that a predetermined magnetic field vector is applied, an offset between the predetermined magnetic field vector and a magnetic field vector measured by the reference sensor 62 may be confirmed, a calibration parameter may be calculated, and the self-calibration of the offset of the reference sensor 62 may be performed by using the calibration parameter.

In some embodiments, magnetic field data (e.g., circular magnetic field data) may be obtained by rotating (e.g., rotating 360 degrees) the calibration member 60 in a magnetic-field applying apparatus or chamber having a predetermined magnetic field, and the self-calibration step S40 of performing the self-calibration of the reference sensor 62 may be performed by using the magnetic field data. The calibration member 60 may have a small size and may obtain the magnetic field data by being rotated in a state that the calibration member 60 is separated from the wafer body portion 10. Accordingly, the self-calibration step S40 of performing the self-calibration of the reference sensor 62 may be performed without risk of a damage of the wafer body portion 10 or the wafer-type magnetic sensor 100a.

In some embodiments, the self-calibration step S40 of performing the self-calibration of the reference sensor 62 may be performed by using a magnetic field vector obtained by the reference sensor 62 in a state that the calibration member 60 is at an area inside a zero gauss chamber with no magnetic field.

In this instance, the self-calibration step S40 of performing the self-calibration of the reference sensor 62 may be performed by one of the above plurality of methods or may be performed by combining at least two of the above plurality of methods. The acceleration data may be considered together in the self-calibration step S40 of performing the self-calibration of the reference sensor 62. Thereby, the precision of the self-calibration of the reference sensor 62 may be enhanced.

When the self-calibration of the reference sensor 62 is complete, the fixing step S42 of fixing the calibration member 60 to the wafer body portion 10 may be performed. The fixing step S42 of fixing the calibration member 60 to the wafer body portion 10 may be performed by a transfer apparatus or an automation logistics system driven by an integrated controller of a manufacturing apparatus of a semiconductor device. However, embodiments of the present disclosure are not limited thereto. The fixing step S42 of fixing the calibration member 60 to the wafer body portion 10 may be manually performed by a worker.

When the fixing step S42 of fixing the calibration member 60 to the wafer body portion 10 is complete, the wafer-type magnetic sensor 100a may be converted to the calibration mode S44. The calibration member 60 may be attached or fixed to the wafer body portion 10 to have a predetermined coordinate by a coordinate alignment portion 68. A circuit portion 30 and/or a calibration circuit portion 66 may perform a coordinate matching calculation for a coordinate alignment of the measuring sensor 20 and the reference sensor 62. The coordinate matching calculation may be performed before the offset calibration step S46, or be performed in the offset calibration step S46.

In the calibration mode S44, the offset calibration step S46 of performing the offset calibration of the measuring sensor 20 may be performed by using reference magnetic field data generated from the reference sensor 62. In a state that the measuring sensor 20 and the reference sensor 62 are exposed by the same magnetic field, each of the measuring sensor 20 and the reference sensor 62 may measure a magnetic field. For example, the measuring sensor 20 and the reference sensor 62 may measure an earth magnetic field.

When the measuring sensor 20 and the reference sensor 62 are exposed by the same magnetic field (e.g., the earth magnetic field), in a state of the coordinate alignment of the measuring sensor 20 and the reference sensor 62 is performed, a magnetic field vector measured by the measuring sensor 20 may be the same as a magnetic field vector measured by the reference sensor 62. The circuit portion 30 and/or the calibration circuit portion 66 may calculate a calibration parameter for converting the magnetic field vector measured by the measuring sensor 20 to be matched to or aligned with the magnetic field vector measured by the reference sensor 62. The offset calibration step S46 of performing of the offset calibration of the measuring sensor 20 may be performed by using the calibration parameter.

When the offset calibration step S46 of performing the offset calibration of the measuring sensor 20 is complete, a completion signal may be provided to the circuit portion 30 or the calibration circuit portion 66. The circuit portion 30 or the calibration circuit portion 66 may convert the wafer-type magnetic sensor 100 to the standby mode. The wafer-type magnetic sensor 100 may wait until the calibration instruction is received. According to embodiments, when a termination instruction exists (e.g., is received), a power supply to the wafer-type magnetic sensor 100a may stop and thus an operation of the wafer-type magnetic sensor 100a may stop.

According to an embodiment, the self-calibration of the reference sensor 62 may be performed in a state that the reference sensor 62 is separated from the wafer body portion 10, and thus, the self-calibration of the reference sensor 62 may be frequently performed using any of various methods without restrictions. For example, the self-calibration of the reference sensor 62 may be separately performed from the unit manufacturing process, and the unit manufacturing process may be prevented from being delayed by the self-calibration of the reference sensor 62.

In an embodiment, the fixing step S42 of fixing the calibration member 60 to the wafer body portion 10 may be performed by a transfer apparatus or an automation logistics system. Thereby, an entire process that performs the offset calibration of the measuring sensor 20 included in the wafer-type magnetic sensor 100a may be automatized or unmanned, thereby enhancing productivity.

FIG. 12 is a perspective view schematically illustrating an example of a manufacturing apparatus of a semiconductor device to which a wafer-type magnetic sensor 100b according to an embodiment is applied. FIG. 13 is a perspective view schematically illustrating the wafer-type magnetic sensor 100b illustrated in FIG. 12. For simple illustration and a clear understanding, a wafer body portion 10 and a measuring sensor 20 of the wafer-type magnetic sensor 100b are mainly illustrated in FIG. 13.

Referring to FIG. 12 and FIG. 13, in an embodiment, a manufacturing apparatus of the semiconductor device may be a wafer carrier 300 configured to accommodate and transfer a wafer 330. For example, the wafer carrier 300 may be a front opening unified pod (FOUP) or a front opening shipping box (FOSB).

In an embodiment, the wafer carrier 300 may include an accommodating portion 310 and a door portion 320. A support member 310a (e.g., a boat) that supports the wafer 330 may be disposed at side surfaces of the accommodating portion 310, and the accommodating portion 310 may have an opening at a side thereof. The door portion 320 may cover the opening of the accommodating portion 310. In FIG. 12, an example of the wafer carrier 300 is illustrated, and a shape, a structure, etc., of the wafer carrier 300 may be variously modified.

In an embodiment, a wafer-type magnetic sensor 100b may include a wafer body portion 10 having a wafer shape and a measuring sensor 20 at or in a wafer body portion 10, and may further include a circuit portion 30 (refer to FIG. 9). The circuit portion 30 may include a controller, a power supplier, a communication interface, a memory, a calculation portion, etc. In an embodiment, the calibrator 40 may be separately provided from the wafer-type magnetic sensor 100b. That is, the calibrator 40 might not be included in the wafer-type magnetic sensor 100b and might not be attached or fixed to the wafer-type magnetic sensor 100b.

Unless otherwise described, the description regarding the wafer-type magnetic sensor 100 with reference to FIG. 1 to FIG. 3 and the description regarding the wafer-type magnetic sensor 100a with reference to FIG. 8 to FIG. 10 may be applied to the wafer-type magnetic sensor 100b according to embodiments. However, embodiments of the present disclosure are not limited thereto. The wafer-type magnetic sensor 100b may have any of various structures.

In an embodiment, the calibrator 40 may include a calibration member 60 that is included in the wafer carrier 300 and includes a reference sensor 62, and may further include a coordinate alignment portion 68 for a coordinate alignment of the reference sensor 62 and the measuring sensor 20.

The calibration member 60 may include the reference sensor 62 and an acceleration sensor 64. The calibration member 60 may include a calibration circuit portion including a calibration controller, a communication interface, etc., or might not include the calibration controller. When the calibration member 60 does not include the calibration controller, an operation of the calibration member 60 may be controlled by a carrier controller that controls the wafer carrier 300 or an integrated controller that controls a manufacturing apparatus of a semiconductor device. Unless otherwise described, the description regarding the calibration member 60 with reference to FIG. 8 to FIG. 10 may be applied to the calibration member 60 according to embodiments.

In an embodiment, the calibration member 60 may be embedded in the wafer carrier 300, may be separably, removably or detachably fixed to the wafer carrier 300, or may be separately disposed from the wafer body portion 10. r

In an embodiment, the coordinate alignment portion 68 may include a magnetic-field applying member 70 that applies a magnetic field to the measuring sensor 20 and the reference sensor 62. The magnetic-field applying member 70 may be a permanent magnet or an electromagnet. For example, the magnetic-field applying member 70 may include a coil.

In an embodiment, the magnetic-field applying member 70 may be disposed at a side surface of the accommodating portion 310. For example, the magnetic-field applying member 70 may be a two-axis Helmholtz coil including two magnetic-field applying members in opposite side surfaces of the accommodating portion 310, respectively. When the magnetic-field applying member 70 is disposed at the side surface(s) of the accommodating portion 310, an additional space might not be needed, thereby reducing a space burden.

The calibration member 60 and the magnetic-field applying member 70 may be disposed so that the magnetic field applied by the magnetic-field applying member 70 is equally applied to the reference sensor 62 included in the calibration member 60 and the measuring sensor 20 included in the wafer-type magnetic sensor 100b. For a clear understanding, FIG. 12 illustrates an example of a position of the calibration member 60, but embodiments of the present disclosure are not limited thereto. A structure, a type, a shape, a position, etc., of the magnetic-field applying member 70 may be variously modified.

The coordinate alignment portion 68 may include a magnetic-field control circuit portion for an operation control of the magnetic-field applying member 70, or might not include the magnetic-field control circuit portion. When the magnetic-field control circuit portion is not included, an operation of the magnetic-field applying member 70 may be controlled by a carrier controller that controls the wafer carrier 300 or an integrated controller that controls a manufacturing apparatus of a semiconductor device.

The wafer-type magnetic sensor 100b may be applied to or included in the manufacturing apparatus of the semiconductor device. That is, the wafer-type magnetic sensor 100b according to an embodiment may measure a magnetic field of a manufacturing apparatus of a semiconductor device using a magnetic field or measure a magnetic field in a manufacturing apparatus of a semiconductor device where a process condition or a property of a final structure may be varied by a magnetic field.

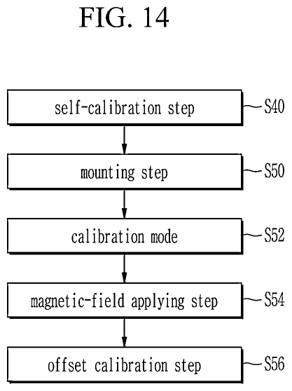

Referring to FIG. 14 together with FIG. 12 to FIG. 13, a calibration method of a wafer-type magnetic sensor 100b according to an embodiment will be described. The calibration method of the wafer-type magnetic sensor 100b according to the embodiment may be performed in a manufacturing process of a semiconductor device.

FIG. 14 is a flowchart illustrating a calibration method of a wafer-type magnetic sensor 100b according to an embodiment.

Referring to FIG. 12 to FIG. 14, in an embodiment, a calibration method of a wafer-type magnetic sensor 100b may include a self-calibration step S40 of performing a self-calibration of a reference sensor 62 included in a calibration member 60, a mounting step S50 of mounting the wafer-type magnetic sensor 100b to a wafer carrier 300, a calibration mode S52, a magnetic-filed applying step S54 of applying a magnetic field for a coordinate alignment, and an offset calibration step S56 of performing an offset calibration of a measuring sensor 20.

In an embodiment, the self-calibration step S40 of performing the self-calibration of the reference sensor 62 may be performed in a state that the calibration member 60 is separated from the wafer carrier 300. In this instance, the calibration member 60 including the reference sensor 62 may be separable, removable, or detachable from the wafer carrier 300, and the self-calibration step S40 of performing the self-calibration of the reference sensor 62 may be freely performed in any of various processes. The description of the self-calibration step S40 with reference to FIG. 11 may be applied to the self-calibration step S40 according to embodiments.

In some embodiments, the self-calibration step S40 may be performed in a state that the calibration member 60 is disposed in the wafer carrier 300.

For example, the reference sensor 62 may be a sensor being capable of performing a self-calibration by using an earth magnetic field, as the reference sensor 50 described in an embodiment with reference to FIG. 1 to FIG. 7. The reference sensor 62 may measure an earth magnetic field data according to a movement of the wafer carrier 300, measured magnetic field data may be obtained, and an offset may be confirmed by the measured magnetic field data. Unless otherwise described, the description regarding the reference sensor 50 with reference to FIG. 1 to FIG. 7 may be applied to the reference sensor 62 being capable of performing the self-calibration by using the earth magnetic field and a self-calibration using the same.

In some embodiments, magnetic field data may be obtained in a state that the magnetic-field applying member 70 embedded in the wafer carrier 300 applies a magnetic field to the reference sensor 62, and the self-calibration of the reference sensor 62 may be performed by using the magnetic field data. For example, the reference sensor 62 may measure magnetic field in a state that a predetermined magnetic field vector is applied, an offset between the predetermined magnetic field vector and the magnetic field vector measured by the reference sensor 62 may be confirmed, a calibration parameter may be calculated, and the self-calibration of the offset of the reference sensor 62 may be performed by using the calibration parameter.

The self-calibration of the reference sensor 62 embedded in the wafer carrier 300 may be performed by any of various methods.

When the self-calibration step S40 of performing the self-calibration of the reference sensor 62 is complete, the mounting step S50 of mounting the wafer-type magnetic sensor 100b to the wafer carrier 300 including the calibration member 60 and the magnetic-field applying member 70 may be performed. When the self-calibration step S40 is performed in a state that the calibration member 60 is separated from the wafer carrier 300, a step of coupling the calibration member 60 to the wafer carrier 300 may be performed. The mounting step S50 of mounting the wafer-type magnetic sensor 100b to the wafer carrier 300 or the step of coupling the calibration member 60 to the wafer carrier 300 may be performed by a transfer apparatus or an automation logistics system driven by an integrated controller of a manufacturing apparatus of a semiconductor device. However, embodiments of the present disclosure are not limited thereto. The mounting step S50 of mounting the wafer-type magnetic sensor 100b to the wafer carrier 300 or the step of coupling the calibration member 60 to the wafer carrier 300 may be manually performed by a worker.

According to embodiments, after performing the self-calibration step S40, the mounting step S50 is performed. In some embodiments, when the calibration member 60 including the reference sensor 62 is embedded in the wafer carrier 300, the self-calibration step S40 may be performed after the mounting step S50.

When the mounting step S50 of mounting the wafer-type magnetic sensor 100b to the wafer carrier 300 is complete, the calibrator 40 and/or the wafer-type magnetic sensor 100b may be converted to the calibration mode S52.

In the calibration mode S52, the magnetic-field applying step S54 of applying a magnetic field for a coordinate alignment and the offset calibration step S56 of performing the offset calibration of the measuring sensor 20 may be performed.

In the magnetic-field applying step S54 of applying the magnetic field for the coordinate alignment, a predetermined magnetic field may be applied to the measuring sensor 20 and the reference sensor 62 for a coordinate alignment of the measuring sensor 20 and the reference sensor 62, and the measuring sensor 20 and the reference sensor 62 may generate magnetic field data regarding the predetermined magnetic field. At least one from among a calibration circuit portion, a circuit portion 30, and an integrated controller may perform a coordinate matching calculation for matching or aligning a coordinate of magnetic field data generated by the measuring sensor 20 and a coordinate of magnetic field data generated by the reference sensor 62.

In the offset calibration step S56 of performing the offset calibration of the measuring sensor 20, each of the measuring sensor 20 and the reference sensor 62 may measure a magnetic field in a state that the measuring sensor 20 and the reference sensor 62 are exposed by the same magnetic field. For example, the measuring sensor 20 and the reference sensor 62 may measure an earth magnetic field or a magnetic field supplied by the magnetic-field applying member 70.

When the measuring sensor 20 and the reference sensor 62 are exposed by the same magnetic field, in a state of the coordinate alignment of the measuring sensor 20 and the reference sensor 62 is performed, a magnetic field vector measured by the measuring sensor 20 may be the same as a magnetic field vector measured by the reference sensor 62. At least one from among the calibration circuit portion, the circuit portion 30, and the integrated controller may calculate a calibration parameter for converting the magnetic field vector measured by the measuring sensor 20 to the magnetic field vector measured by the reference sensor 62, and perform the offset calibration of the measuring sensor 20 by using the calibration parameter.

In FIG. 14, it is illustrated as an example that the magnetic-field applying step S54 is a separate step from the offset calibration step S56. In some embodiments, a coordinate matching calculation and the offset calibration of the measuring sensor 20 may be performed together by applying the magnetic field to the measuring sensor 20 and the reference sensor 62 in the offset calibration step S56. In some embodiments, the magnetic field applied to the measuring sensor 20 and the reference sensor 62 in the magnetic-field applying step S54 may be different from the magnetic field to which the measuring sensor 20 and the reference sensor 62 are exposed in the offset calibration step S56.

In an embodiment, the offset calibration step S56 may be performed in a transfer process where the wafer-type magnetic sensor 100b is in the wafer carrier 300. However, embodiments of the present disclosure are not limited thereto.

According to an embodiment, the offset calibration of the measuring sensor 20 may be performed in the wafer carrier 300 and thus the offset calibration of the measuring sensor 20 may be performed without an additional apparatus or process. Accordingly, a process for the offset calibration of the measuring sensor 20 may be simplified and calibration time may be minimized.

In an embodiment, the mounting step S50 of mounting the wafer-type magnetic sensor 100b to the wafer carrier 300 may be performed by a transfer apparatus or an automation logistics system. Thereby, an entire process that performs the offset calibration of the measuring sensor 20 included in the wafer-type magnetic sensor 100b may be automatized or unmanned, thereby enhancing productivity.

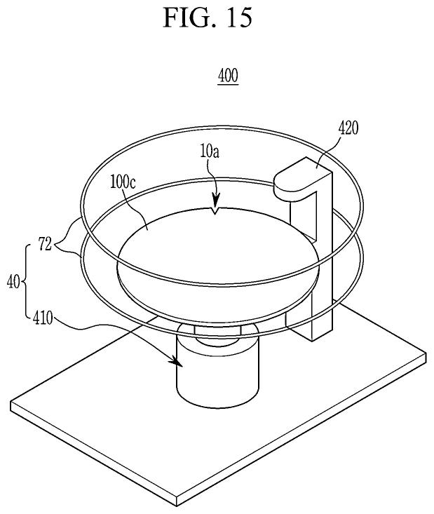

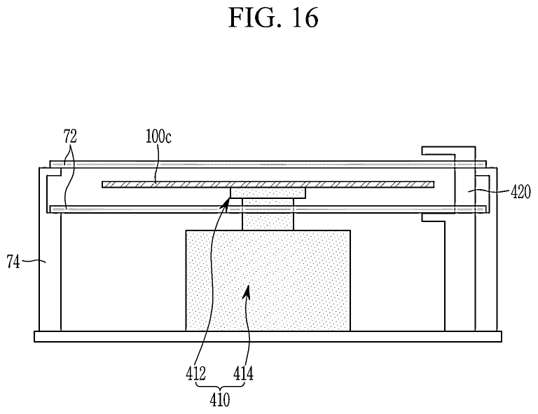

FIG. 15 is a perspective view schematically illustrating an example of a manufacturing apparatus of a semiconductor device to which a wafer-type magnetic sensor 100c according to an embodiment is applied. FIG. 16 schematically illustrates the manufacturing apparatus of the semiconductor device illustrated in FIG. 15. For simple illustration and a clear understanding, a magnetic-field applying member 72 is schematically illustrated in FIG. 15.

Referring to FIG. 15 and FIG. 16, in an embodiment, a manufacturing apparatus of a semiconductor device may be a wafer aligner 400 for an alignment of a wafer. The wafer aligner 400 may detect a notch 10a or a flat zone of a wafer-type magnetic sensor 100c or a wafer to align the wafer-type magnetic sensor 100c or the wafer. For example, the wafer aligner 400 may be included in a unit manufacturing apparatus to align the wafer.

In an embodiment, the wafer aligner 400 may include a rotation member 410 and a sensor portion 420 (e.g., a sensor). The wafer may be on an upper portion of the rotation member 410, and the rotation member 410 may horizontally rotate the wafer-type magnetic sensor 100c or the wafer. The sensor portion 420 may detect the notch 10a or the flat zone of the wafer-type magnetic sensor 100c or the wafer. The rotation member 410 may include a supporting member 412 (e.g., a wafer chuck) that supports the wafer-type magnetic sensor 100c or the wafer on the upper surface of the rotation member 410, and a driver 414 (e.g., an actuator (e.g., a motor)) that is connected to the supporting member 412 and horizontally rotates the supporting member 412.

When the wafer or the wafer-type magnetic sensor 100c is disposed on the upper portion of the supporting member 412, the supporting member 412 may be rotated by the driver 414 to rotate the wafer or the wafer-type magnetic sensor 100c. The sensor portion 420 may detect the notch 10a or the flat zone of the wafer-type magnetic sensor 100c or the wafer to align the wafer-type magnetic sensor 100c or the wafer.

In an embodiment, the wafer-type magnetic sensor 100c may include a wafer body portion having a wafer shape and a measuring sensor 20 at or in a wafer body portion, and may further include a circuit portion. The circuit portion may include a controller, a power supplier, a communication interface, a memory, a calculation portion, etc. In an embodiment, a calibrator 40 may be separately provided from the wafer-type magnetic sensor 100c. That is, the calibrator 40 might not be included in the wafer-type magnetic sensor 100c and might not be attached or fixed to the wafer-type magnetic sensor 100c.

The wafer-type magnetic sensor 100c according to an embodiment may be the wafer-type magnetic sensor 100b described with reference to FIG. 12 and FIG. 13. Unless otherwise described, the description regarding the wafer-type magnetic sensor 100b with reference to FIG. 12 and FIG. 13 may be applied to the wafer-type magnetic sensor 100c according to embodiments. However, embodiments of the present disclosure are not limited thereto. The wafer-type magnetic sensor 100c may have any of various structures.

In an embodiment, the calibrator 40 may be included in the wafer aligner 400. The calibrator 40 may include the rotation member 410 and the magnetic-field applying member 72. The rotation member 410 may horizontally rotate (e.g., rotate in an xy plane) the wafer-type magnetic sensor 100c. The magnetic-field applying member 72 may apply a magnetic field to the wafer-type magnetic sensor 100c. The magnetic-field applying member 72 may apply a magnetic field to the wafer-type magnetic sensor 100c in a vertical direction (e.g., a z-axis direction).

The magnetic-field applying member 72 may be a permanent magnet or an electromagnet. For example, the magnetic-field applying member 72 may include a coil. In an embodiment, the magnetic-field applying member 72 may be a two-axis Helmholtz coil including two magnetic-field applying members at a lower portion and an upper portion of the wafer-type magnetic sensor 100c, respectively. Thereby, the magnetic field may be applied in a desirable direction by a simple structure. However, embodiments of the present disclosure are not limited thereto. A structure, a type, a shape, a position, etc., of the magnetic-field applying member 72 may be variously modified.

In FIG. 16, it is illustrated as an example that the magnetic-field applying member 72 is fixed at a predetermined position by a frame 74 that structurally supports the magnetic-field applying member 72. However, embodiments of the present disclosure are not limited thereto. The magnetic-field applying member 72 may be fixed at a predetermined position by any of various structures, types, etc.

In some embodiments, a magnetic-field control circuit portion for an operation control of the magnetic-field applying member 72 may be further included. In some embodiments, an operation of the magnetic-field applying member 72 may be controlled by an aligner controller that controls the wafer aligner 400 or an integrated controller that controls a manufacturing apparatus of a semiconductor device.

In an embodiment, the rotation member 410 included in the wafer aligner 400 is used as a part of the calibrator 40, an equipment may be easily implemented by adding the magnetic field application member 72 to the wafer aligner 400.

The wafer-type magnetic sensor 100c may be applied to or included in the manufacturing apparatus of the semiconductor device. That is, the wafer-type magnetic sensor 100c according to an embodiment may measure a magnetic field of a manufacturing apparatus of a semiconductor device using a magnetic field or measure a magnetic field in a manufacturing apparatus of a semiconductor device where a process condition or a property of a final structure may be varied by a magnetic field.

According to embodiments, the wafer aligner 400 including the rotation member 410 may be an example of the manufacturing apparatus of the semiconductor device including the calibrator 40. However, embodiments of the present disclosure are not limited thereto. The calibrator 40 may be included in an apparatus including a rotation member used in a manufacturing process of a semiconductor device. For example, the calibrator 40 may be included in an apparatus including a spin member (e.g., a spin coating apparatus).

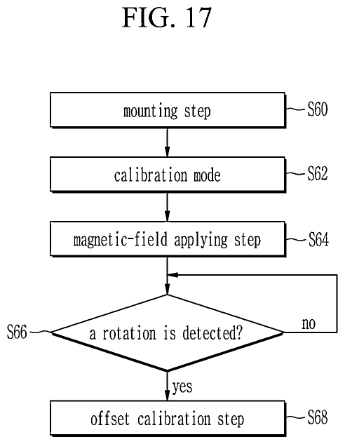

Referring to FIG. 17 together with FIG. 15 to FIG. 16, a calibration method of a wafer-type magnetic sensor 100c according to an embodiment will be described. The calibration method of the wafer-type magnetic sensor 100c according to the embodiment may be performed in a manufacturing process of a semiconductor device.

FIG. 17 is a flowchart illustrating a calibration method of a wafer-type magnetic sensor 100c according to an embodiment.

Referring to FIG. 15 to FIG. 17, in an embodiment, a calibration method of a wafer-type magnetic sensor 100c may include a mounting step S60 of mounting a wafer-type magnetic sensor 100c to a wafer aligner 400, a calibration mode S62, a magnetic-field applying step S64 of applying a magnetic field to the wafer-type magnetic sensor 100c in a vertical direction in a state that the wafer-type magnetic sensor 100 is horizontally rotated, a rotation detecting step S66 of detecting whether the wafer-type magnetic sensor 100c rotates, and an offset calibration step S68 of performing an offset calibration of a measuring sensor 20.

First, the mounting step S60 of mounting the wafer-type magnetic sensor 100c to the wafer aligner 400 may be performed. More particularly, the wafer-type magnetic sensor 100c may be mounted on a supporting member 412. The mounting step S60 of mounting the wafer-type magnetic sensor 100c to the wafer aligner 400 may be performed by a transfer apparatus driven by an aligner controller that controls an operation of the wafer aligner 400, an apparatus controller that controls an operation of a unit manufacturing apparatus including the wafer aligner 400, or an integrated controller that controls a manufacturing apparatus of a semiconductor device.

When the mounting step S60 of mounting the wafer-type magnetic sensor 100c to the wafer aligner 400 is complete, a calibrator 40 and/or the wafer-type magnetic sensor 100c may be converted to the calibration mode S62.

In the calibration mode S62, the magnetic-field applying step S64 of applying a magnetic field to the wafer-type magnetic sensor 100c in a vertical direction in a state that the wafer-type magnetic sensor 100 is horizontally rotated may be performed. The wafer-type magnetic sensor 100c may be horizontally rotated by the rotation member 410, and the magnetic field may be applied in the vertical direction by the magnetic-field applying member 72.

In this instance, when a rotation of the wafer-type magnetic sensor 100c is detected in the rotation detecting step S66 of detecting whether the wafer-type magnetic sensor 100c rotates, the offset calibration step S68 of performing the offset calibration of the measuring sensor 20 may be performed. Here, the rotation of the wafer-type magnetic sensor 100c may refer to a rotation that allows for the offset calibration of the measuring sensor 20.

In the offset calibration step S68 of performing the offset calibration of the measuring sensor 20, offset calibrations in an x-axis and a y-axis may be performed based on magnetic field data in an xy plane by a horizontal rotation, and an offset calibration in a z-axis may be performed based on magnetic field data measuring the magnetic field applied by the magnetic-field applying member 72.

In an embodiment, by obtaining repeated measurement data at the same rotation angle through changing a rotation number, a rotation speed, etc., of the rotation member 410, a signal-to-noise ratio may be enhanced and thus precision in the offset calibration of the measuring sensor 20 may be enhanced. In some embodiments, the precision in the offset calibration of the measuring sensor 20 may be enhanced by using a calibration algorithm in consideration of angle variables.

In an embodiment, the offset calibration of the measuring sensor 20 included in the wafer-type magnetic sensor 100c may be performed in an alignment process performed in a unit manufacturing apparatus, and thus, the measuring sensor 20 may be maintained in a zero-offset state without an additional process. In some embodiments, an alignment process that includes the offset calibration of the measuring sensor 20 may be performed when the wafer-type magnetic sensor 100c is discharged from the unit manufacturing apparatus. In an embodiment, the wafer-type magnetic sensor 100c is horizontally rotated and thus a damage of the wafer-type magnetic sensor 100c may be minimized.

The calibration mode S62 of the wafer-type magnetic sensor 100c may be performed before a measuring mode of the wafer-type magnetic sensor 100c or may be performed after the measuring mode of the wafer-type magnetic sensor 100c.

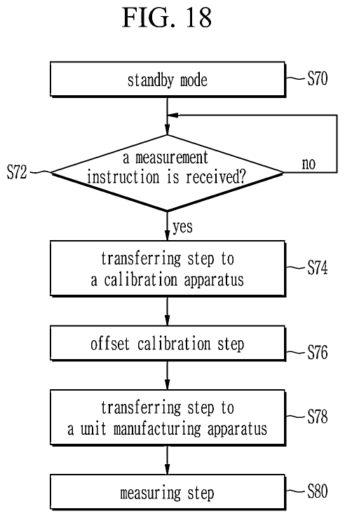

FIG. 18 is a flowchart illustrating a calibration method of a wafer-type magnetic sensor according to an embodiment.

Referring to FIG. 18, in an embodiment, a calibration method of a wafer-type magnetic sensor may include a standby mode S70, a measurement-instruction determination step S72 of determining whether a measurement instruction is received, a transferring step S74 of transferring a wafer-type magnetic sensor to a calibration apparatus, an offset calibration step S76 of performing an offset calibration of a measuring sensor in the calibration apparatus, a transferring step S78 of transferring the wafer-type magnetic sensor to a unit manufacturing apparatus, and a measuring step S80 of measuring a magnetic field by a measuring sensor.

In the standby mode S70, the measurement-instruction determination step S72 of determining whether a measurement instruction is received or not may be performed. When the measurement instruction is not received, the wafer-type magnetic sensor may be maintained in the standby mode S70. When the measurement instruction is received in the standby mode S70, the transferring step S74 of transferring the wafer-type magnetic sensor to the calibration apparatus may be performed. The transferring step S74 of transferring the wafer-type magnetic sensor to the calibration apparatus may be performed by a transfer apparatus or an automation logistics system driven by an integrated controller of a manufacturing apparatus of a semiconductor device.

The offset calibration step S76 of performing the offset calibration of the measuring sensor included in the wafer-type magnetic sensor may be performed in the calibration apparatus. The calibration apparatus may be any of various apparatuses that is capable of controlling a magnetic field. The calibration apparatus may be an apparatus including a magnetic-field applying member and/or a zero gauss chamber. The apparatus including the magnetic-field applying member may include a three-axis Helmholtz coil. However, embodiments of the present disclosure are not limited thereto. A structure, a type, a shape, a position, etc., of the apparatus including the magnetic-field applying member may be variously modified.

For example, in the offset calibration step S76 of performing the offset calibration of the measuring sensor, the offset calibration of the measuring sensor may be performed by using magnetic field data obtained in a state the magnetic-field applying member included in the calibration apparatus applies a magnetic field to the wafer-type magnetic sensor including the measuring sensor. For example, the measuring sensor may measure magnetic field in a state that a predetermined magnetic field vector is applied, an offset between the predetermined magnetic field vector and magnetic field vector measured by the measuring sensor may be confirmed, and the offset calibration of the measuring sensor may be performed by using the offset.

In some embodiments, in the offset calibration step S76 of performing the offset calibration of the measuring sensor, an offset calibration of the measuring sensor may be performed by using a magnetic field vector obtained by the measuring sensor in a state that the wafer-type magnetic sensor is at an area inside a zero gauss chamber with no magnetic field.

In an embodiment, the offset calibration of the measuring sensor may be performed by one of the above plurality of methods or may be performed by combining at least two of the above plurality of methods.

When the offset calibration of the measuring sensor is complete, the transferring step S78 of transferring the wafer-type magnetic sensor to the unit manufacturing apparatus may be performed, and then, the measuring step S80 of measuring a magnetic field by the measuring sensor may be performed. The transferring step S78 of transferring the wafer-type magnetic sensor to the unit manufacturing apparatus may be performed by a transfer apparatus or an automation logistics system driven by an integrated controller of a manufacturing apparatus of a semiconductor device.

Thereby, an entire process that performs the offset calibration of the measuring sensor included in the wafer-type magnetic sensor may be automatized or unmanned in a line of a manufacturing process of a semiconductor device through an integrated controller or an automation system.

According to embodiments of the present disclosure, any number (e.g., some or all) of the steps of the methods described above with reference to FIG. 5, FIG. 6, FIG. 11, FIG. 14, FIG. 17, and FIG. 18 may be performed by at least one controller. For example, the at least one controller may include at least one processor and memory storing computer instructions that are configured to, when executed by the at least one processor, cause the at least one controller to perform its functions. For example, the at least one controller may be or include, or be included in, at least one from among a circuit portion 30, a controller 32, a calculation portion 34d, a calibration controller 66a, an integrated controller, a carrier controller, an aligner controller, an apparatus controller, etc., that is described above.

According to embodiments of the present disclosure, some of the steps of the methods described above with reference to FIG. 5, FIG. 6, FIG. 11, FIG. 14, FIG. 17, and FIG. 18 may be performed by a first set (e.g., one or more) of controllers from among the controllers, and other steps among the steps may be performed by a second set (e.g., one or more) of controllers from among the controllers.

While some non-limiting example embodiments have been described in connection with the drawings, it is to be understood that the present disclosure is not limited thereto, and that various modifications and equivalent arrangements are included within the spirit and scope of the present disclosure.

What is claimed is:

1. A manufacturing apparatus of a semiconductor device, comprising:
a wafer-type magnetic sensor comprising a wafer body portion and at least one measuring sensor at or in the wafer body portion; and
a calibrator configured to perform an offset calibration of the at least one measuring sensor.

2. The manufacturing apparatus of the semiconductor device of claim 1, wherein the calibrator comprises at least one reference sensor having a signal-to-noise ratio that is greater than a signal-to-noise ratio of the at least one measuring sensor.

3. The manufacturing apparatus of the semiconductor device of claim 2, wherein the at least one reference sensor is in the wafer body portion.

4. The manufacturing apparatus of the semiconductor device of claim 1, wherein the calibrator comprises at least one reference sensor that is configured to provide reference magnetic field data for the offset calibration of the at least one measuring sensor, and
wherein the calibrator further comprises a coordinate alignment portion that is configured to perform a coordinate alignment of the at least one reference sensor and the at least one measuring sensor.

5. The manufacturing apparatus of the semiconductor device of claim 4, wherein:
the coordinate alignment portion comprises a guide structure configured to perform the coordinate alignment of the at least one reference sensor and the at least one measuring sensor, and the guide structure is in the wafer body portion; or
the coordinate alignment portion comprises a sensor for the coordinate alignment of the at least one reference sensor and the at least one measuring sensor; or
the coordinate alignment portion comprises a magnetic-field applying member that is configured to apply a magnetic field to the at least one measuring sensor and the at least one reference sensor for the coordinate alignment of the at least one reference sensor and the at least one measuring sensor.

6. The manufacturing apparatus of the semiconductor device of claim 1, wherein the calibrator comprises a calibration member that comprises at least one reference sensor, and
wherein the calibration member is separately disposed from the wafer body portion or is separable, removable, or detachable from the wafer body portion.

7. The manufacturing apparatus of the semiconductor device of claim 1, wherein the calibrator comprises a calibration member that comprises at least one reference sensor, and
wherein the calibration member is in a wafer carrier that is configured to accommodate and transfer a wafer.

8. The manufacturing apparatus of the semiconductor device of claim 1, wherein the calibrator comprises at least one reference sensor that is configured to provide reference magnetic field data for the offset calibration of the at least one measuring sensor, and
wherein the at least one measuring sensor is a plurality of measuring sensors and a number of the at least one reference sensor is less than a number of the plurality of measuring sensors.

9. The manufacturing apparatus of the semiconductor device of claim 1, wherein the calibrator comprises:
a rotation member that is configured to rotate the wafer-type magnetic sensor in a plane; and
a magnetic-field applying member that is configured to apply a magnetic field to the wafer-type magnetic sensor.

10. The manufacturing apparatus of the semiconductor device of claim 9, wherein the magnetic-field applying member is configured to apply the magnetic field to the wafer-type magnetic sensor in a vertical direction.

11. The manufacturing apparatus of the semiconductor device of claim 9, wherein the calibrator is included in an apparatus that includes the rotation member.

12. The manufacturing apparatus of the semiconductor device of claim 1, wherein the calibrator comprises an acceleration sensor.

13. A manufacturing apparatus of a semiconductor device, comprising:
a wafer-type magnetic sensor comprises:
a wafer body portion;
a measuring sensor at or in the wafer body portion; and
a calibrator comprising a reference sensor, the calibrator configured to perform an offset calibration of the measuring sensor.

14. The manufacturing apparatus of claim 13, wherein the reference sensor has a signal-to-noise ratio that is greater than a signal-to-noise ratio of the measuring sensor.

15. The manufacturing apparatus of claim 14, wherein the reference sensor is included in the wafer body portion.

16. The manufacturing apparatus of claim 14, wherein the reference sensor is configured to provide reference magnetic field data for the offset calibration of the measuring sensor, and
wherein the calibrator further comprises a coordinate alignment portion configured to perform a coordinate alignment of the reference sensor and the measuring sensor.

17. A manufacturing apparatus of a semiconductor device, comprising:
a wafer-type magnetic sensor comprising a wafer body portion and at least one measuring sensor at or in the wafer body portion; and
a calibrator configured to perform, during a manufacturing process of a semiconductor device by the manufacturing apparatus, an offset calibration of the at least one measuring sensor.

18. The manufacturing apparatus of claim 17, wherein the performing the offset calibration comprises:
obtaining, by a reference sensor, reference magnetic field data;
obtaining, by the measuring sensor, magnetic field data; and
performing the offset calibration of the measuring sensor based on the reference magnetic field data and the magnetic field data,
wherein the reference sensor is included in the wafer-type magnetic sensor, or the reference sensor and the measuring sensor are exposed to a same magnetic field during the obtaining the reference magnetic field data and the obtaining the magnetic field data, respectively.

19. The manufacturing apparatus of claim 18, wherein the manufacturing apparatus performs, before the performing the offset calibration of the measuring sensor, a self-calibration of the reference sensor in a transfer process of the wafer-type magnetic sensor.

20. The manufacturing apparatus of claim 17, wherein the performing the offset calibration comprises:
obtaining, by the measuring sensor, magnetic field data during an alignment process of the wafer-type magnetic sensor in which the wafer-type magnetic sensor is rotated in a plane and a magnetic field is applied to the wafer-type magnetic sensor in a vertical direction; and
performing the offset calibration of the measuring sensor based on the magnetic field data.
